(19) United States
(12) Patent Application Publication
(10) Pub. No.: US 2025/0299767 A1
(43) Pub. Date: Sep. 25, 2025

(54) OPERATIONAL MODES OF A MEMORY REGISTER

(71) Applicant: Micron Technology, Inc., Boise, ID (US)

(72) Inventors: Suhas Shivapakash, München (DE); Fabien Funfrock, München (DE); Elena Cabrera Bernal, München (DE); Jens Polney, Feldkirchen (DE)

(21) Appl. No.: 19/075,572

(22) Filed: Mar. 10, 2025

Related U.S. Application Data
(60) Provisional application No. 63/568,100, filed on Mar. 21, 2024.

(51) Int. Cl. G11C 29/56

(52) U.S. Cl. CPC G11C 29/56012

(57) ABSTRACT

Methods, systems, and devices for operational modes of a memory register are described. For example, a memory system may operate a register as a shift register, a multiple-input shift register (MISR) circuit, and a linear-feedback shift register (LFSR) circuit based on inputs provided to the register via respective multiplexers. In some instances, the register may operate as a shift register and a seed may be loaded to the associated flip-flops. The register may switch operational modes and may operate as a MISR circuit to test a data path between the associated memory system and a host system in the write direction. The register may also switch operational modes and may operate as a LFSR circuit to test the data path in the read direction. The register may operate in the respective modes based on inputs provided.

### CROSS REFERENCE

The present Application for Patent claims priority to U.S. Patent Application No. 63/568,100 by Shivapakash et al., entitled “OPERATIONAL MODES OF A MEMORY REGISTER,” filed Mar. 21, 2024, which is assigned to the assignee hereof, and which is expressly incorporated by reference in its entirety herein.

### TECHNICAL FIELD

The following relates to one or more systems for memory, including operational modes of a memory register.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports operational modes of a memory register in accordance with examples as disclosed herein.

FIG. 2 shows an example of a circuit that supports operational modes of a memory register in accordance with examples as disclosed herein.

FIG. 3 shows an example of a process flow that supports operational modes of a memory register in accordance with examples as disclosed herein.

FIG. 4 shows a block diagram of a memory system that supports operational modes of a memory register in accordance with examples as disclosed herein.

FIG. 5 shows a flowchart illustrating a method or methods that support operational modes of a memory register in accordance with examples as disclosed herein.

### DETAILED DESCRIPTION

A memory system may include various circuits to perform different testing operations. For example, a memory system may include different circuits that are coupled with an interface to test read operations (e.g., to test a data path associated with data read from a memory device) and write operations (e.g., to test a data path associated with data received from a host system). To initialize a test, starting data (e.g., a seed) may be loaded into a circuit (e.g., a multiple-input shift register (MISR)) via the interface. In some instances, the MISR and interface may operate according to different clock frequencies, which may add complexities to a testing operation. Moreover, the presence of the interface and the MISR may occupy a relatively large space within the memory system. Accordingly, simplified circuit for testing operations that occupies a relatively smaller space within a memory system may be desirable.

A memory system that includes a simplified testing circuit that occupies a relatively small space is described herein. For example, a memory system may include a register (e.g., a shift register) that includes multiple flip-flops. The input of each flip-flop may be coupled with a first multiplexer having multiple inputs. The first multiplexers may be configured to select an input to the shift register. The input may include a seed, data received from a host system, or an output from the register (e.g., a feedback loop). Additionally, or alternatively, the shift register may be coupled with a second multiplexer configured to select a clock frequency for the shift register. The second multiplexer may select an input to the shift register. The input may include a clock frequency associated with a seed setting operation, a read testing operation, or a write testing operation. Accordingly, such a simplified circuit may reduce complexities that would have otherwise occurred due to the different operations operating at different clock frequencies. Moreover, the circuit described herein may occupy a relatively smaller space than existing testing circuits.

In addition to applicability in memory systems as described herein, techniques for operational modes of a memory register may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds and reducing materials used in production of electronic devices, which may decrease processing or latency times, improve response times, or otherwise improve user experience, while decreasing product size, among other benefits.

Features of the disclosure are illustrated and described in the context of systems and architectures. Features of the disclosure are further illustrated and described in the context of circuits, process flows, and flowcharts.

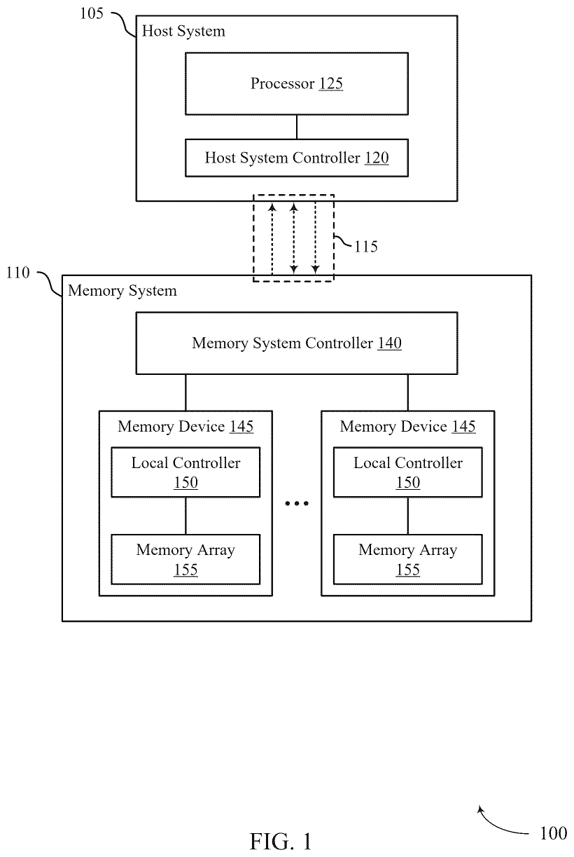

FIG. 1 illustrates an example of a system 100 that supports operational modes of a memory register in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not- or (NOR) memory cells, and not- and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

The memory system 110 may include a register (e.g., a shift register) that includes multiple flip-flops. The input of each flip-flop may be coupled with a first multiplexer having multiple inputs. The first multiplexers may be configured to select an input to the shift register, and the input may include a seed or data received from a host system 105. Additionally, or alternatively, the shift register may be coupled with a second multiplexer configured to select a clock frequency for the shift register. The second multiplexer may select an input to the shift register, and the input may include a clock frequency associated with a seed setting operation, a read testing operation, or a write testing operation.

Accordingly, such a simplified circuit may reduce complexities that would have otherwise occurred due to the different operations operating at different clock frequencies. Moreover, the circuit described herein may occupy a relatively smaller space within the memory system 110 than existing testing circuits.

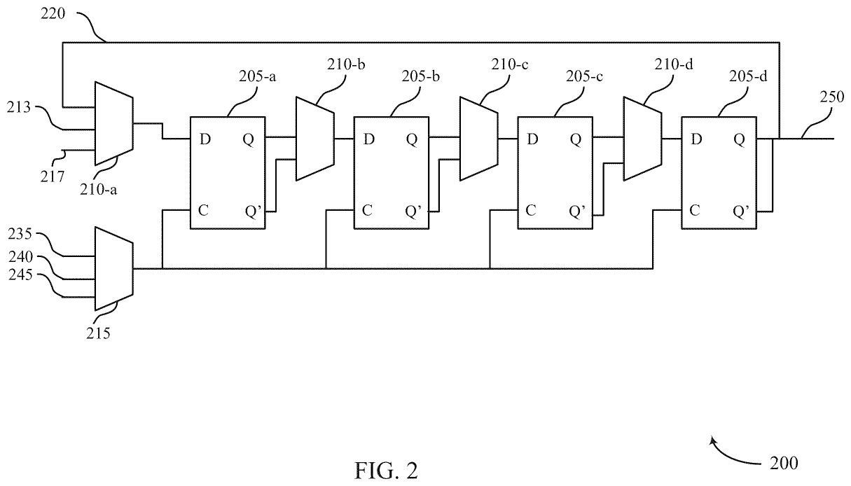

FIG. 2 illustrates an example of circuit diagram 200 that supports operational modes of a memory register in accordance with examples as disclosed herein. In some instances, the circuit depicted by the circuit diagram 200 may be included in the system 100, may be used to test aspects of the system 100, or both. For example, the circuit may test the channels 115 in the read direction (e.g., from the memory system 110 to the host system 105) and in the write direction (e.g., from the host system 105 to the memory system 110). The circuit depicted by the circuit diagram 200 may be simplified relative to existing solutions, which may complexities that would have otherwise occurred due to the different operations operating at different clock frequencies. Moreover, the circuit may occupy a relatively smaller space within the memory system 110 than existing testing circuits.

The circuit diagram 200 illustrates a register circuit that may include one or more flip-flops 205, one or more first multiplexers 210, and one or more second multiplexers 215. For example, the circuit diagram 200 may include one or more flip-flops 205. The flip-flops 205 may be cascaded together, such that an output of a first flip-flop 205-a is coupled with an input of a second flip-flop 205-b. In some examples, the flip-flop 205-a may receive a data input via the first multiplexer 210-a, and may output data to the first multiplexer 210-b, which may output this data to the flip-flop 205-b (e.g., the flip-flop 205-b may receive a data input via the first multiplexer 210-b). Additionally, or alternatively, each flip-flop 205 may also be coupled with an output of a second multiplexer 215.

In some examples, the flip-flops 205 may be examples of D flip-flops 205 (e.g., a D-type flip-flop 205). A D flip-flop 205 may be referred to as a “delay flip-flop” or a “data flip-flop” and may be used to store single bit of data. In some examples, a D flip-flop 205 may be synchronous or asynchronous. As described herein, the flip-flops 205 may be examples of a synchronous D flip-flop, which may include (e.g., require) a clock input to function. As illustrated with reference to FIG. 2, a D flip-flop 205 may include two inputs: data (D) and clock (C) to control the respective flip-flop 205. When the clock input is high, the data is transferred to the output of the flip-flop, whereas when the clock input is low, the output of the flip-flop 205 may be held in its previous state.

In some instances, the flip-flops may include two outputs, Q and Q′, and may operate as follows. For example, when the clock signal is low, the flip-flop 205 may hold its current state and ignore the D input. When the clock signal is high, the flip-flop 205 may sample and store the D input. The value that was previously fed into the D input may reflected at the output Q of the flip-flop 205. That is, if D=0, then Q=0, whereas if D=1, then Q=1. Additionally, or alternatively, the Q′ output of a flip-flop 205 may be complemented by the Q output. For example, if Q=0, then Q′=1, and if Q=1, then Q′=0. Such D flip-flops 205 may be relatively simple to design and operate, and may be relatively fast compared to other digital logic devices.

The flip-flops 205 may each be coupled with a respective multiplexer. For example, the flip-flop 205-a may be coupled with a first multiplexer 210-a that is coupled with a plurality of input lines. The input lines may be coupled with an interface (e.g., a P1500 interface) that is not shown. In some examples, the first multiplexer 210-a may be a 3:1 multiplexer. That is, the first multiplexer 210-a may be coupled with a first data line and a second data line 217. The first multiplexer 210-a may also be coupled with an output of the register via a third data line 220. The first multiplexer 210-a may also include a control line (not shown) that is coupled with a memory system controller (e.g., a memory system controller 140 as described with reference to FIG. 1).

In some instances, the multiplexer 210-b, multiplexer 210-c, and multiplexer 210-d may all be 2:1 multiplexers. Each of the 2:1 multiplexers may be coupled with an output of a respective flip-flop 205. For example, the outputs Q and Q′ of the flip-flop 205-a may be coupled (e.g., as inputs) with the multiplexer 210-b. Each of the multiplexer 210-b, multiplexer 210-c, and multiplexer 210-d may include respective control lines coupled with a memory system controller. As used herein, the multiplexers 210 may collectively be referred to as a first plurality of multiplexers 210. Additionally, or alternatively, the multiplexers 210 may each include any quantity of input lines, which may be a matter of design choice.

In other examples, the flip-flops 205 may each be coupled with a second multiplexer 215. For example, the clock (C) input of flip-flop 205 may be coupled with a second multiplexer 215 that is coupled with a plurality of input lines. The input lines may be coupled with an interface (e.g., a P1500 interface) that is not shown. In some examples, the second multiplexer 215 may be a 3:1 multiplexer. That is, the second multiplexer 215 may be coupled with a first clock line, a second clock line, and a third clock line. The second multiplexer 215 may also include a control line (not shown) that is coupled with a memory system controller (e.g., a memory system controller 140 as described with reference to FIG. 1).

The register depicted by the circuit diagram 200 may operate in various modes. For example, the register may operate as a shift register, a MISR circuit, and a LFSR circuit. As described herein, register may operate as a shift register when the flip-flops 205 are seeded, and when the register is read out after a MISR test. The register may operate in a MISR mode to accumulate data from a host system perform a first testing operation. A first testing operation may test a data path between an associated memory system and host system in the write direction. As used herein, the write direction may refer to data being received (e.g., by a memory system) from a host system. The register may also operate in a LFSR mode to perform a second testing operation. A second testing operation may test the read direction, which may include generating and providing a pseudorandom data stream to a host system. As used herein, the read direction may refer to data being transmitted to a host system.

In some instances, the register may be first operated as a shift register to seed the flip-flops 205. In some instances, the flip-flops 205 may be seeded based on an input received via the first data line 213 and the first clock line 235. That is, the seed may be provided to the multiplexer 210-a via the first data line 213 when a first clock signal having a first frequency is provided to the clock inputs of the flip-flops 205. The control lines coupled with the multiplexer 210-a and the multiplexer 215 may be selected (e.g., driven to a high value), and the seed data and first clock signal may be provided to the flip-flops 205. As used herein, the seed or the seed data may refer to the initial data provided to the flip-flops 205.

When seeding the flip-flops 205, the initial data may be provided to the flip-flop 205-a, which may output a result (e.g., via Q or Q′) as an input to the multiplexer 210-b. A control line of the multiplexer 210-b may be selected, and the data may be provided to the flip-flop 205-b, which may output a result (e.g., via Q or Q′) as an input to the multiplexer 210-c. A control line of the multiplexer 210-c may be selected, and the data may be provided to the flip-flop 205-c, which may output a result (e.g., via Q or Q′) as an input to the multiplexer 210-d. A control line of the multiplexer 210-d may be selected, and the data may be provided to the flip-flop 205-d.

After seeding the flip-flops 205, the register may switch operational modes to operate in a MISR mode. To switch operational modes, the first data line 213 and the first clock line 235 may be deselected. In some instances, the first data line 213 and the first clock line 240 may be deselected after the control lines of the respective multiplexers are deselected (e.g., driven to a low value). The second data line 217 and the second clock line 240 may then be selected. That is, data received from a host system may be provided to the multiplexer 210-a via the second data line 217 when a second clock signal having a second frequency is provided to the clock inputs of the flip-flops 205. The control lines coupled with the multiplexer 210-a and the multiplexer 215 may be selected (e.g., driven to a high value), and the host data and second clock signal may be provided to the flip-flops 205.

When operating in a MISR mode, the host data may be provided to the flip-flop 205-a, which may output a result (e.g., via Q or Q′) as an input to the multiplexer 210-b. The host data may include N data bits, where N represents the quantity of flip-flops 205 included in the register. In other examples, N may be defined based on a width of the bus (e.g., the data bus) coupled with the host system and the memory system. A control line of the multiplexer 210-b may be selected, and the data may be provided to the flip-flop 205-b, which may output a result (e.g., via Q or Q′) as an input to the multiplexer 210-c. A control line of the multiplexer 210-c may be selected, and the data may be provided to the flip-flop 205-c, which may output a result (e.g., via Q or Q′) as an input to the multiplexer 210-d. A control line of the multiplexer 210-d may be selected, and the data may be provided to the flip-flop 205-d.

In some instances, the register may switch back to a shift register mode after the testing operation is complete, and the register may read out the results of the test (e.g., the MISR signature). In some examples, an output of the flip-flop 205-d may be coupled with an output line 250, one or more pins, or both such that the result may be provided (e.g., transmitted) to a host system or other device.

After performing a write direction testing operation, the register may switch operational modes to operate in a LFSR mode. To switch operational modes, the second data line 217 and the second clock line 240 may be deselected. In some instances, the second data line 217 and the second clock line 240 may be deselected after the control lines of the respective multiplexers are deselected (e.g., driven to a low value). The third data line 220 and the third clock line 245 may then be selected. That is, data output from the flip-flop 205-d may be provided as an input to the flip-flop 205-a when a third clock signal having a third frequency is provided to the clock inputs of the flip-flops 205. Such a loop (e.g., a feedback loop) may generate a pseudorandom data stream which may be output (e.g., transmitted) to a host system to test the read direction of the bus.

When operating in a LFSR mode, the output of the flip-flop 205-d may be provided to the flip-flop 205-a, which may output a result (e.g., via Q or Q′) as an input to the multiplexer 210-b. A control line of the multiplexer 210-b may be selected, and the data may be provided to the flip-flop 205-b, which may output a result (e.g., via Q or Q′) as an input to the multiplexer 210-c. A control line of the multiplexer 210-c may be selected, and the data may be provided to the flip-flop 205-c, which may output a result (e.g., via Q or Q′) as an input to the multiplexer 210-d. A control line of the multiplexer 210-d may be selected, and the data may be provided to the flip-flop 205-d. In some instances, the pseudorandom data stream may be provided to a host system while the register is operating in a LFSR mode (e.g., without switching to a shift register mode).

In some instances, the circuit depicted by the circuit diagram 200 may operate in various modes according to the description herein and provided below with reference to Table 1.

TABLE 1

| | First Clock | Second Clock | Third Clock | | |
|---|---|---|---|---|---|
| Configuration | Signal | Signal | Signal | Input | Output |
| Seed data | X | — | — | Shift register | — |
| | | | | input | |
| LFSR mode | — | X | — | — | N data bits |
| MISR mode | — | — | X | N data bits | — |
| Readout | X | — | — | First data | Shift register |
| | | | | | output |

Accordingly, such a simplified circuit depicted by the circuit diagram 200 may reduce complexities that would have otherwise occurred due to the different operations operating at different clock frequencies. That is, the presence of the multiplexer 215 may allow for the register to operate according to three distinct clock cycles. Moreover, the circuit described herein may occupy a relatively smaller space within a memory system 110 than existing testing circuits.

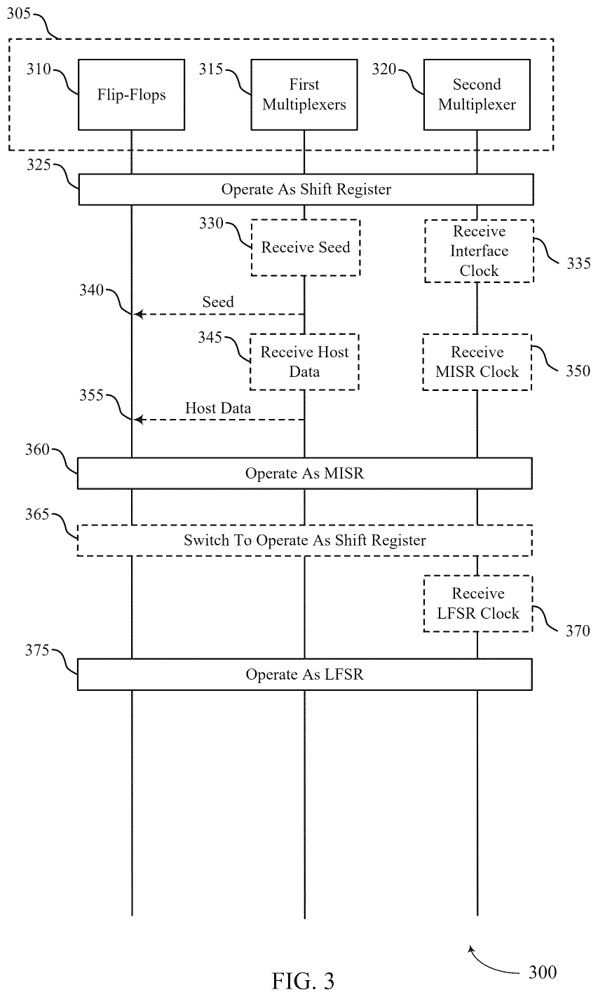

FIG. 3 shows an example of a process flow 300 that supports operational modes of a memory register in accordance with examples as disclosed herein. Aspects of the process flow 300 may implement, or be implemented by, aspects of the system 100, the circuit diagram 200, or a combination thereof. For example, the process flow 300 may illustrate various signaling and operations that may enable a register circuit to be operable in different modes depending on the status and needs of an associated memory system.

The process flow 300 illustrates aspects performed at or by a register 305 that may include one or more flip-flops 310, one or more first multiplexers 315, and a second multiplexer 320, which may be examples of one or more flip-flops 205, one or more first multiplexers 210, and a second multiplexer 215, respectively, as illustrated in FIG. 2. The register may be included in or associated with a memory system, which may be an example of a memory system 110 as illustrated in FIG. 1.

In some examples, the operations illustrated in process flow 300 may be performed by hardware (e.g., including circuitry, processing blocks, logic components, and other components), code such as processor-executable code (e.g., software or firmware) executed by a processor, or any combination thereof. Alternative examples of the following may be implemented, where some steps are performed in a different order than described or are not performed at all. In some cases, steps may include additional features not mentioned below, or further steps may be added.

At 325, the register 305 may operate as a shift register circuit. For example, at 325 a first clock signal having a first frequency may be provided to the shift register. In some examples, the first clock signal may be associated with or provided by a interface of the memory system. When operating as a shift register, the one or more flip-flops 310 may receive a first input from the memory system (e.g., from the interface).

At 330, the one or more first multiplexers 315 may receive an input. The input may include a seed which, as described herein, may refer to the initial data programmed to the register 305 to enable testing operations. The input may be provided to the first multiplexers 315 from an interface, such as a P1500 circuit.

At 335, the one or more second multiplexers 320 may receive an input. The input may include a clock associated with an interface, such as a P1500 circuit. The clock may be associated with a first frequency associated with the interface, such that the register 305 operates according to the first frequency when the seed is received. The one or more second multiplexers 320 may provide the clock signal to the flip-flops 310. For example, a memory system controller or other component of a memory system may select a control signal associated with one or more of the second multiplexers 320, which may result in the clock provided to the flip-flops 310.

At 340, the one or more first multiplexers 315 may provide the seed to the flip-flops 310. For example, a memory system controller or other component of a memory system may select a control signal associated with one or more of the first multiplexers 315, which may result in the seed being provided to the flip-flops 310. The seed may be provided to each of the flip-flops 310 prior to initiating one or more testing operations and, in some examples, may be provided to the flip-flops 310 before the interface clock is received (e.g., at 335).

At 345, the one or more first multiplexers 315 may receive an input. The input may include data received from a host system, which may be used by the register 305 to test a data path between the memory system and host system. The data received from the host system may include N data bits, where N is equal to the quantity of flip-flops 310 included in the register 305. In some instances, when the input is received by the first multiplexers 315, the register 305 may operate in a MISR mode (e.g., the register 305 may operate as a MISR).

At 350, the one or more second multiplexers 320 may receive an input. The input may include a clock associated with MISR operations, such as testing the data path between the memory system and the host system in the write direction. The clock may be associated with a second frequency, such that the register 305 operates according to the second frequency when the host data is received.

At 355, the one or more first multiplexers 315 may provide the host data to the flip-flops 310. For example, a memory system controller or other component of a memory system may select a control signal associated with one or more of the first multiplexers 315, which may result in the host data being provided to the flip-flops 310. The host data may be provided to each of the flip-flops 310 before the MISR clock is received (e.g., at 350). The one or more second multiplexers 320 may provide the MISR clock signal to the flip-flops 310. For example, a memory system controller or other component of a memory system may select a control signal associated with one or more of the second multiplexers 320, which may result in the MISR clock provided to the flip-flops 310.

At 360, the register 305 may operate as a MISR circuit based on the received host data and MISR clock. For example, the register 305 may switch from operating as a shift register to operating as a MISR circuit based on the host data and MISR clock inputs. When operating as a MISR circuit, the flip-flops 310 may accumulate the host data and may output one or more bits (e.g., via one or more pins coupled with the register 305) that indicate a result of the testing operation.

At 365, the register 305 may switch from operating as a MISR circuit to operating as a shift register (e.g., for a second time). In some instances, the register 305 may switch operational functionality based on the inputs to the flip-flops 310. That is, inputs associated with the host data and MISR clock may be disabled, and inputs associated with the interface may be provide to the respective multiplexers. For example, an input the same as or similar to the seed data may be provide to the first multiplexers 315 and the interface clock may be provide to the second multiplexer 320. Based on the respective inputs, the register 305 may read out the content of the flip-flops 310 (e.g., the MISR signature, the result of testing the write operation) via one or more pins. The result of the readout may indicate whether errors may exist in the data path between the memory system and host system in the write direction.

At 370, the one or more second multiplexers 320 may receive an input. The input may include a clock associated with LFSR operations, such as testing the data path between the memory system and the host system in the read direction. The clock may be associated with a third frequency, such that the register 305 operates according to the third frequency operating in a LFSR mode.

At 375, the register 305 may operate as a LFSR circuit based on the received LFSR clock. For example, the register 305 may switch from operating as a shift register to operating as a LFSR circuit based on the LFSR clock input. In some instances, when operating in a LFSR mode, the register 305 may not receive data from an outside source (e.g., a host system). Instead, the register 305 may utilize the seed to generate and output a pseudorandom data stream to the host system. As described herein, the pseudorandom data stream may test the data path between the memory system and the host system in the read direction.

In some examples, the register 305 may switch back to operating as a shift register (or a MISR circuit) after operating as the LFSR circuit (e.g., at 375). For example, in response to operating as a LFSR circuit, the register 305 may switch back to shift register circuit operations by disabling the LFSR clock and respective receiving inputs (e.g., at the first multiplexers 315 and second multiplexer 320). In other examples, the register 305 may operate as a shift register, MISR circuit, and LFSR circuit in any order, including orders different than explained herein with reference to FIG. 3. By being able to switch between such operations, the associated circuit may be simplified by reducing complexities that would have otherwise occurred due to the different operations operating at different clock frequencies, and may be occupy a relatively smaller space within a memory system than existing testing circuits.

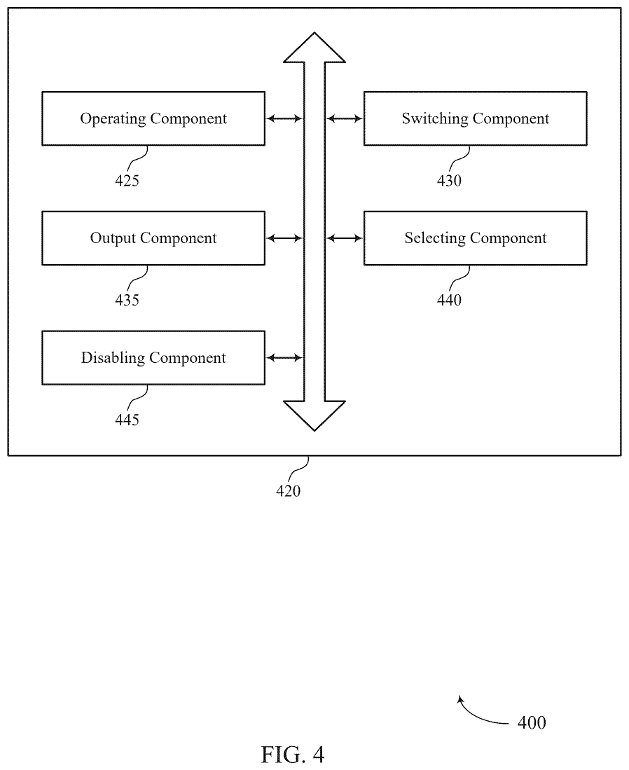

FIG. 4 shows a block diagram 400 of a memory system 420 that supports operational modes of a memory register in accordance with examples as disclosed herein. The memory system 420 may be an example of aspects of a memory system as described with reference to FIGS. 1 through 3. The memory system 420, or various components thereof, may be an example of means for performing various aspects of operational modes of a memory register as described herein. For example, the memory system 420 may include an operating component 425, a switching component 430, an output component 435, a selecting component 440, a disabling component 445, or any combination thereof. Each of these components, or components of subcomponents thereof (e.g., one or more processors, one or more memories), may communicate, directly or indirectly, with one another (e.g., via one or more buses).

The operating component 425 may be configured as or otherwise support a means for operating a register including a plurality of flip-flops as a shift register circuit associated with a first clock signal at a first frequency, where the shift register circuit is configured to receive a first data input. The switching component 430 may be configured as or otherwise support a means for switching the register to operate as a multiple-input signal register (MISR) circuit after operating the register as the shift register circuit. In some examples, the operating component 425 may be configured as or otherwise support a means for operating the register as the MISR circuit associated with a second clock signal at a second frequency based at least in part on a second data input to the register, where the MISR circuit is associated with a first testing operation associated with data received from a host device. In some examples, the switching component 430 may be configured as or otherwise support a means for switching the register to operate as a linear-feedback shift register (LFSR) circuit after operating the register as the MISR circuit. In some examples, the operating component 425 may be configured as or otherwise support a means for operating the register as the LFSR circuit associated with a third clock signal at a third frequency, where the LFSR circuit is associated with a second testing operation associated with data read from a memory device.

In some examples, the first data input to the register includes a seed for the plurality of flip-flops.

In some examples, the switching component 430 may be configured as or otherwise support a means for switching the register to operate as the shift register circuit after operating the register as the MISR circuit. In some examples, the operating component 425 may be configured as or otherwise support a means for operating, for a second time, the register as the shift register circuit associated with the first clock signal at the first frequency based at least in part on switching the register to operate as the shift register circuit for the second time. In some examples, the output component 435 may be configured as or otherwise support a means for outputting a first value from the register based at least in part on operating the register as the shift register circuit for the second time, where the first value is associated with a result of the first testing operation.

In some examples, switching the register to operate as the LFSR circuit includes disabling the second data input to the register.

In some examples, the shift register circuit is configured to receive the first data input via a first data line. In some examples, selecting the second data input to the register includes selecting a second data line.

In some examples, the switching component 430 may be configured as or otherwise support a means for switching the register to operate as the shift register circuit after operating the register as the LFSR circuit. In some examples, the operating component 425 may be configured as or otherwise support a means for operating, for a third time, the register as the shift register circuit associated with the first clock signal at the first frequency based at least in part on switching the register to operate as the shift register circuit for the third time. In some examples, the output component 435 may be configured as or otherwise support a means for outputting a second value from the register based at least in part on operating the register as the shift register circuit for the third time, where the second value is associated with a result of the second testing operation.

In some examples, the selecting component 440 may be configured as or

otherwise support a means for selecting the second data input to the register, where operating the register of the memory system as the MISR circuit is based at least in part on selecting the second data input.

In some examples, the shift register circuit is configured to receive the first data input according to the first clock signal at the first frequency.

In some examples, to support switching the register to operate as the LFSR circuit, the disabling component 445 may be configured as or otherwise support a means for disabling a second clock input to the register that is associated with the second clock signal. In some examples, to support switching the register to operate as the LFSR circuit, the selecting component 440 may be configured as or otherwise support a means for selecting a third clock input to the register that is associated with the third clock signal based at least in part on disabling the second clock input to the register that is associated with the second clock signal.

In some examples, selecting the third clock input to the register includes selecting the third clock line.

In some examples, the switching component 430 may be configured as or otherwise support a means for switching the register of the memory system to operate as the MISR circuit based at least in part on operating the register as the LFSR circuit.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

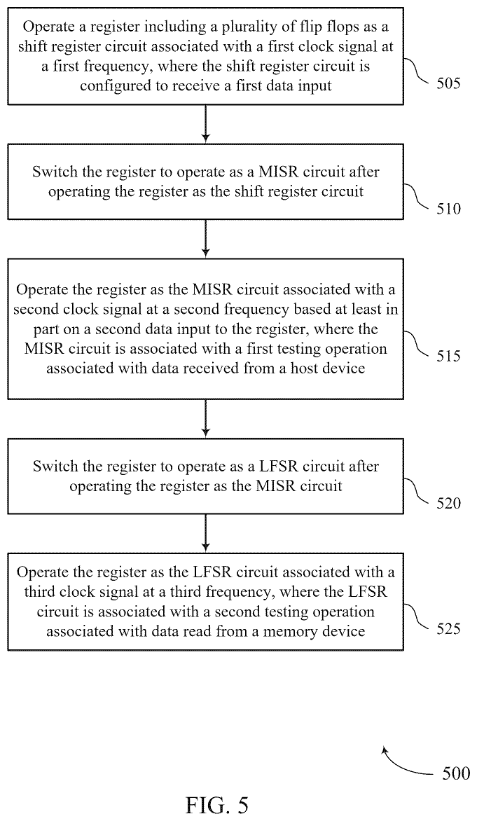

FIG. 5 shows a flowchart illustrating a method 500 that supports operational modes of a memory register in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include operating a register including a plurality of flip-flops as a shift register circuit associated with a first clock signal at a first frequency, where the shift register circuit is configured to receive a first data input. In some examples, aspects of the operations of 505 may be performed by an operating component 425 as described with reference to FIG. 4.

At 510, the method may include switching the register to operate as a MISR circuit after operating the register as the shift register circuit. In some examples, aspects of the operations of 510 may be performed by a switching component 430 as described with reference to FIG. 4.

At 515, the method may include operating the register as the MISR circuit associated with a second clock signal at a second frequency based at least in part on a second data input to the register, where the MISR circuit is associated with a first testing operation associated with data received from a host device. In some examples, aspects of the operations of 515 may be performed by an operating component 425 as described with reference to FIG. 4.

At 520, the method may include switching the register to operate as a LFSR circuit after operating the register as the MISR circuit. In some examples, aspects of the operations of 520 may be performed by a switching component 430 as described with reference to FIG. 4.

At 525, the method may include operating the register as the LFSR circuit associated with a third clock signal at a third frequency, where the LFSR circuit is associated with a second testing operation associated with data read from a memory device. In some examples, aspects of the operations of 525 may be performed by an operating component 425 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for operating a register including a plurality of flip-flops as a shift register circuit associated with a first clock signal at a first frequency, where the shift register circuit is configured to receive a first data input; switching the register to operate as a multiple-input signal register (MISR) circuit after operating the register as the shift register circuit; operating the register as the MISR circuit associated with a second clock signal at a second frequency based at least in part on a second data input to the register, where the MISR circuit is associated with a first testing operation associated with data received from a host device; switching the register to operate as a linear-feedback shift register (LFSR) circuit after operating the register as the MISR circuit; and operating the register as the LFSR circuit associated with a third clock signal at a third frequency, where the LFSR circuit is associated with a second testing operation associated with data read from a memory device.
Aspect 2: The method, apparatus, or non-transitory computer-readable medium of aspect 1, where the first data input to the register includes a seed for the plurality of flip-flops.
Aspect 3: The method, apparatus, or non-transitory computer-readable medium of any of aspects 1 through 2, further including operations, features, circuitry, logic, means, or instructions, or any combination thereof for switching the register to operate as the shift register circuit after operating the register as the MISR circuit; operating, for a second time, the register as the shift register circuit associated with the first clock signal at the first frequency based at least in part on switching the register to operate as the shift register circuit for the second time; and outputting a first value from the register based at least in part on operating the register as the shift register circuit for the second time, where the first value is associated with a result of the first testing operation.
Aspect 4: The method, apparatus, or non-transitory computer-readable medium of aspect 3, where switching the register to operate as the LFSR circuit includes disabling the second data input to the register.
Aspect 5: The method, apparatus, or non-transitory computer-readable medium of aspect 4, where the shift register circuit is configured to receive the first data input via a first data line and selecting the second data input to the register includes selecting a second data line.
Aspect 6: The method, apparatus, or non-transitory computer-readable medium of any of aspects 1 through 5, further including operations, features, circuitry, logic, means, or instructions, or any combination thereof for switching the register to operate as the shift register circuit after operating the register as the LFSR circuit; operating, for a third time, the register as the shift register circuit associated with the first clock signal at the first frequency based at least in part on switching the register to operate as the shift register circuit for the third time; and outputting a second value from the register based at least in part on operating the register as the shift register circuit for the third time, where the second value is associated with a result of the second testing operation.
Aspect 7: The method, apparatus, or non-transitory computer-readable medium of any of aspects 1 through 6, further including operations, features, circuitry, logic, means, or instructions, or any combination thereof for selecting the second data input to the register, where operating the register of the memory system as the MISR circuit is based at least in part on selecting the second data input.
Aspect 8: The method, apparatus, or non-transitory computer-readable medium of any of aspects 1 through 7, where the shift register circuit is configured to receive the first data input according to the first clock signal at the first frequency.
Aspect 9: The method, apparatus, or non-transitory computer-readable medium of aspect 8, where switching the register to operate as the LFSR circuit includes operations, features, circuitry, logic, means, or instructions, or any combination thereof for disabling a second clock input to the register that is associated with the second clock signal and selecting a third clock input to the register that is associated with the third clock signal based at least in part on disabling the second clock input to the register that is associated with the second clock signal.
Aspect 10: The method, apparatus, or non-transitory computer-readable medium of aspect 9, where selecting the third clock input to the register includes selecting the third clock line.
Aspect 11: The method, apparatus, or non-transitory computer-readable medium of any of aspects 1 through 10, further including operations, features, circuitry, logic, means, or instructions, or any combination thereof for switching the register of the memory system to operate as the MISR circuit based at least in part on operating the register as the LFSR circuit.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 12: A memory system, including: a register including a plurality of flip-flops, where the register is configured to operate as a shift register circuit associated with a first clock signal during a first duration, a multiple-input signal register (MISR) circuit associated with a second clock signal during a second duration, and a linear-feedback shift register (LFSR) circuit associated with a third clock signal during a third duration different than the first duration and the second duration; a plurality of first multiplexers coupled with the register, a first multiplexer of the plurality of first multiplexers coupled with a flip-flop of the plurality of flip-flops, where the register is configured to operate as the shift register circuit based at least in part on a first data input to the plurality of flip-flops and operate as the MISR circuit based at least in part on a second data input to the plurality of first multiplexers; and a second multiplexer coupled with the register, where the first clock signal is provided to the register based at least in part on a first clock input to the second multiplexer, the second clock signal is provided to the register based at least in part on a second clock input to the second multiplexer, and the third clock signal is provided to the register based at least in part on a third clock input to the second multiplexer.
Aspect 13: The memory system of aspect 12, where the first data input to the register includes a seed for the plurality of flip-flops.
Aspect 14: The memory system of any of aspects 12 through 13, where the MISR circuit is associated with a first testing operation associated with data received from a host device, and the LFSR circuit is associated with a second testing operation associated with data read from a memory device.
Aspect 15: The memory system of any of aspects 12 through 14, where a first flip-flop of the plurality of flip-flops is cascaded with a second flip-flop of the plurality of flip-flops.
Aspect 16: The memory system of any of aspects 12 through 15, where the register is configured to operate as the MISR circuit based at least in part on selecting the second data input to the plurality of first multiplexers and the second clock input to the second multiplexer.
Aspect 17: The memory system of any of aspects 12 through 16, where the register is configured to operate as the LFSR circuit based at least in part on selecting a third data input to the plurality of first multiplexers and the third clock input to the second multiplexer.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium.

Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method by a memory system, comprising:
operating a register comprising a plurality of flip-flops as a shift register circuit associated with a first clock signal at a first frequency, wherein the shift register circuit is configured to receive a first data input;
switching the register to operate as a multiple-input signal register (MISR) circuit after operating the register as the shift register circuit;
operating the register as the MISR circuit associated with a second clock signal at a second frequency based at least in part on a second data input to the register, wherein the MISR circuit is associated with a first testing operation associated with data received from a host device;
switching the register to operate as a linear-feedback shift register (LFSR) circuit after operating the register as the MISR circuit; and
operating the register as the LFSR circuit associated with a third clock signal at a third frequency, wherein the LFSR circuit is associated with a second testing operation associated with data read from a memory device.

2. The method of claim 1, wherein the first data input to the register comprises a seed for the plurality of flip-flops.

3. The method of claim 1, further comprising:
switching the register to operate as the shift register circuit after operating the register as the MISR circuit;
operating, for a second time, the register as the shift register circuit associated with the first clock signal at the first frequency based at least in part on switching the register to operate as the shift register circuit for the second time; and
outputting a first value from the register based at least in part on operating the register as the shift register circuit for the second time, wherein the first value is associated with a result of the first testing operation.

4. The method of claim 3, wherein switching the register to operate as the LFSR circuit comprises disabling the second data input to the register.

5. The method of claim 4, wherein:
the shift register circuit is configured to receive the first data input via a first data line, and
selecting the second data input to the register comprises selecting a second data line.

6. The method of claim 1, further comprising:
switching the register to operate as the shift register circuit after operating the register as the LFSR circuit;
operating, for a third time, the register as the shift register circuit associated with the first clock signal at the first frequency based at least in part on switching the register to operate as the shift register circuit for the third time; and
outputting a second value from the register based at least in part on operating the register as the shift register circuit for the third time, wherein the second value is associated with a result of the second testing operation.

7. The method of claim 1, further comprising:
selecting the second data input to the register, wherein operating the register of the memory system as the MISR circuit is based at least in part on selecting the second data input.

8. The method of claim 1, wherein the shift register circuit is configured to receive the first data input according to the first clock signal at the first frequency.

9. The method of claim 8, wherein switching the register to operate as the LFSR circuit comprises:
disabling a second clock input to the register that is associated with the second clock signal; and
selecting a third clock input to the register that is associated with the third clock signal based at least in part on disabling the second clock input to the register that is associated with the second clock signal.

10. The method of claim 9, wherein the shift register circuit is configured to receive the first clock signal via a first clock line, the second clock signal via a second clock line, and a third clock signal via a third clock line, wherein selecting the third clock input to the register comprises selecting the third clock line.

11. The method of claim 1, further comprising:
switching the register of the memory system to operate as the MISR circuit based at least in part on operating the register as the LFSR circuit.

12. A memory system, comprising:
a register comprising a plurality of flip-flops, wherein the register is configured to operate as a shift register circuit associated with a first clock signal during a first duration, a multiple-input signal register (MISR) circuit associated with a second clock signal during a second duration, and a linear-feedback shift register (LFSR) circuit associated with a third clock signal during a third duration different than the first duration and the second duration;
a plurality of first multiplexers coupled with the register, a first multiplexer of the plurality of first multiplexers coupled with a flip-flop of the plurality of flip-flops, wherein the register is configured to operate as the shift register circuit based at least in part on a first data input to the plurality of flip-flops and operate as the MISR circuit based at least in part on a second data input to the plurality of first multiplexers; and
a second multiplexer coupled with the register, wherein the first clock signal is provided to the register based at least in part on a first clock input to the second multiplexer, the second clock signal is provided to the register based at least in part on a second clock input to the second multiplexer, and the third clock signal is provided to the register based at least in part on a third clock input to the second multiplexer.

13. The memory system of claim 12, wherein the first data input to the register comprises a seed for the plurality of flip-flops.

14. The memory system of claim 12, wherein:
the MISR circuit is associated with a first testing operation associated with data received from a host device, and
the LFSR circuit is associated with a second testing operation associated with data read from a memory device.

15. The memory system of claim 12, wherein a first flip-flop of the plurality of flip-flops is cascaded with a second flip-flop of the plurality of flip-flops.

16. The memory system of claim 12, wherein the register is configured to operate as the MISR circuit based at least in part on selecting the second data input to the plurality of first multiplexers and the second clock input to the second multiplexer.

17. The memory system of claim 12, wherein the register is configured to operate as the LFSR circuit based at least in part on selecting a third data input to the plurality of first multiplexers and the third clock input to the second multiplexer.

18. A memory system, comprising:
a register; and
processing circuitry coupled with the register and configured to cause the memory system to:
operate a register comprising a plurality of flip-flops as a shift register circuit associated with a first clock signal at a first frequency, wherein the shift register circuit is configured to receive a first data input;
switch the register to operate as a multiple-input signal register (MISR) circuit after operating the register as the shift register circuit;
operate the register as the MISR circuit associated with a second clock signal at a second frequency based at least in part on a second data input to the register, wherein the MISR circuit is associated with a first testing operation associated with data received from a host device;
switch the register to operate as a linear-feedback shift register (LFSR) circuit after operating the register as the MISR circuit; and
operate the register as the LFSR circuit associated with a third clock signal at a third frequency, wherein the LFSR circuit is associated with a second testing operation associated with data read from a memory device.

19. The memory system of claim 18, wherein the first data input to the register comprises a seed for the plurality of flip-flops.

20. The memory system of claim 18, wherein the processing circuitry is further configured to cause the memory system to:
switch the register to operate as the shift register circuit after operating the register as the MISR circuit;
operate, for a second time, the register as the shift register circuit associated with the first clock signal at the first frequency based at least in part on switching the register to operate as the shift register circuit for the second time; and
output a first value from the register based at least in part on operating the register as the shift register circuit for the second time, wherein the first value is associated with a result of the first testing operation.

21. The memory system of claim 20, wherein switching the register to operate as the LFSR circuit comprises disabling the second data input to the register.

22. The memory system of claim 21, wherein:
the shift register circuit is configured to receive the first data input via a first data line, and
selecting the second data input to the register comprises selecting a second data line.

23. The memory system of claim 18, wherein the processing circuitry is further configured to cause the memory system to:
switch the register to operate as the shift register circuit after operating the register as the LFSR circuit;
operate, for a third time, the register as the shift register circuit associated with the first clock signal at the first frequency based at least in part on switching the register to operate as the shift register circuit for the third time; and
output a second value from the register based at least in part on operating the register as the shift register circuit for the third time, wherein the second value is associated with a result of the second testing operation.

24. The memory system of claim 18, wherein the processing circuitry is further configured to cause the memory system to:
select the second data input to the register, wherein operating the register of the memory system as the MISR circuit is based at least in part on selecting the second data input.

25. The memory system of claim 24, wherein the shift register circuit is configured to receive the first data input according to the first clock signal at the first frequency.
